(19) United States
(12) Patent Application Publication
(10) Pub. No.: US 2019/0159366 A1
(43) Pub. Date: May 23, 2019

(54) TEMPERATURE CONTROL DEVICE AND METHOD THEREOF

(71) Applicants: INVENTEC (PUDONG) TECHNOLOGY CORPORATION, Shanghai City (CN); INVENTEC CORPORATION, Taipei City (TW)

(72) Inventors: Cheng-Ming LEE, Taipei City (TW); Kai-Yang TUNG, Taipei City (TW); Mao-Ching LIN, Taipei City (TW); Shan-Heng WU, Taipei City (TW); Wei-Yu CHEN, Taipei City (TW)

(73) Assignees: INVENTEC (PUDONG) TECHNOLOGY CORPORATION, Shanghai City (CN); INVENTEC CORPORATION, Taipei City (TW)

(21) Appl. No.: 15/867,602

(22) Filed: Jan. 10, 2018

(30) Foreign Application Priority Data
Nov. 17, 2017 (CN) 201711142141.7

(51) Int. Cl. H05K 7/20

(52) U.S. Cl. CPC H05K 7/20836; H05K 7/20718

(57) ABSTRACT

A temperature-controlling method adapted to a server comprises: getting a detected temperature; selecting a schedule from a plurality of schedules according to the detected temperature by a gain-scheduling unit, wherein the plurality of schedules comprises an initial parameter set and at least one cooling parameter set; calculating and outputting a control signal of fan speed according to the initial parameter set or said at least one cooling parameter set by a PID controller; and adjusting a rotating speed according to the control signal of fan speed by a fan.

### CROSS-REFERENCE TO RELATED APPLICATIONS

This non-provisional application claims priority under 35 U.S.C. § 119(a) on Patent Application No(s). 201711142141.7 filed in China on Nov. 17, 2017, the entire contents of which are hereby incorporated by reference.

### TECHNICAL FIELD

This disclosure relates to a temperature control method, and more particularly to the method for controlling a fan speed.

### RELATED ART

The most difficult term in server's evaluation is the heat dissipation. For achieving a high performance, the server must have a robust cooling capability. Otherwise, the overheated components will affect the reliability of the system, and the server may even crash without warning. Increasing the fan speed to promote the convection between hot air and cold air inside the server is a common method for ruling out the waste heat inside the server. However, the traditional method that the adjustment of the fan speed is corresponding to the sensing temperature easily leads to over-cooling thus consuming extra power. Under the consideration of saving unnecessary power consumption, the feedback control technology has been introduced into the fan speed control, and the Proportional-Integral-Derivative (PID) controller is the most common technology.

The PID controller comprises a self-defined continuity equation and a plurality of coefficients corresponding to the proportional term, the derivative term, and the integral control term in the equation. The fan control system can achieve a better performance by adjusting the PID coefficients.

### SUMMARY

According to one or more embodiments of this disclosure, a temperature control device adapted to a server, comprising: a fan, a temperature sensor, a gain-scheduling sensor and a PID controller. The fan is configured to drive airflows for controlling a temperature of a controlled area. The temperature sensor is disposed in the controlled area for getting a detected temperature of the controlled area. The gain-scheduling unit electronically connects to the temperature sensor, wherein the gain-scheduling unit selects a schedule from a plurality of schedules according to the detected temperature, and the plurality of schedules comprises an initial parameter set and at least one cooling parameter set, said at least one cooling parameter set at least comprises a first parameter set and a second parameter set; the gain-scheduling unit selects the initial parameter set when the detected temperature is greater than or equal to an initial temperature and is less than a first temperature, the gain-scheduling unit selects the first parameter set when the detected temperature is greater than or equal to the first temperature and is less than a second temperature, the gain-scheduling unit selects the second parameter set when the detected temperature is greater than or equal to the second temperature; wherein the second temperature is greater than the first temperature and the first temperature is greater than the initial temperature. The PID controller electronically connects to the fan and the gain-scheduling unit for selectively controlling the fan according to the initial parameter set or said at least one cooling parameter set.

According to one or more embodiments of this disclosure, a temperature control method adapted to a server, comprising: getting a detected temperature of a controlled area of the server by a temperature sensor; selecting a schedule from a plurality of schedules according to the detected temperature by a gain-scheduling unit, wherein the plurality of schedules comprises an initial parameter set and at least one cooling parameter set, the gain-scheduling unit selects the initial parameter set when the detected temperature is greater than or equal to an initial temperature and is less than a first temperature, the gain-scheduling unit selects the first parameter set when the detected temperature is greater than or equal to the first temperature and is less than a second temperature, the gain-scheduling unit selects the second parameter set when the detected temperature is greater than or equal to the second temperature; wherein the second temperature is greater than the first temperature and the first temperature is greater than the initial temperature; calculating and outputting a control signal of fan speed according to the initial parameter set or said at least one cooling parameter set by a PID controller; and adjusting a speed according to the control signal of fan speed by a fan.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a schematic view of a temperature control device according to an embodiment of the present disclosure;

FIG. 2 is a flowchart of a temperature control method according to an embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

The present disclosure provides a temperature control device adapted to a server. The temperature control device is configured to control a temperature of a controlled area to approach to a threshold temperature, wherein the controlled area is such as a specified space or an electronic component in the server, and the threshold temperature is such as a temperature of the normally operating electronic component of the controlled area.

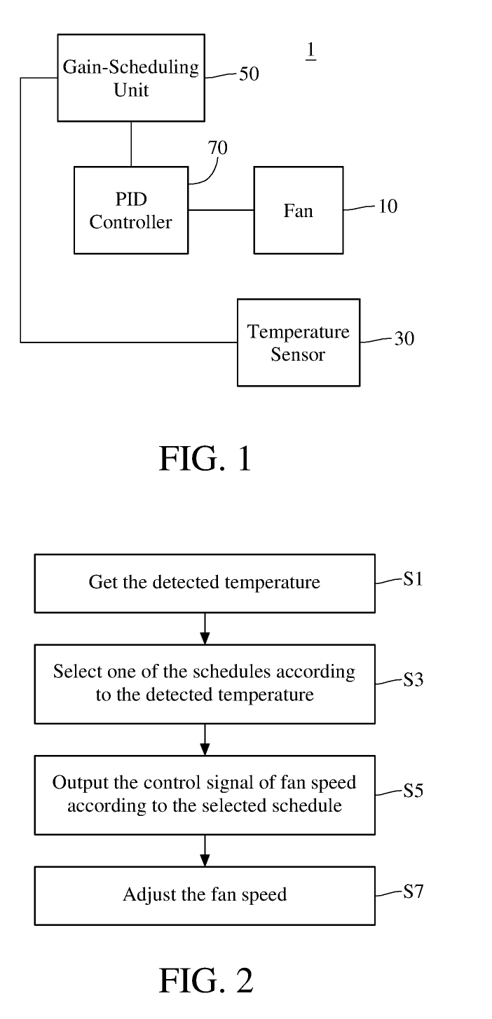

Please refer to FIG. 1, which is a schematic view of the temperature control device according to an embodiment of the present disclosure. As shown in FIG. 1, the temperature control device comprises a fan 10, a temperature sensor 30, a gain-scheduling unit 50 and a PID (Proportional-Integrated-Derivative) controller 70. The gain-scheduling unit 50 electronically connects to the fan 10 and the PID controller 70, and the PID controller 70 electronically connects to the fan 10.

The fan 10 drives airflows by its operations to decrease the temperature of the controlled area. The temperature sensor 30 is such as a thermocouple, a thermistor, an RTD (Resistance temperature detector) or an IC (Integrated Circuit) temperature detector. The present disclosure does not limit the type or the number of the temperature sensor 30. The temperature sensor 30 is disposed in the controlled area to get a detected temperature. The detected temperature is such as a temperature of said specified space in the server or the temperature of the electronic component in the server.

The gain scheduling is an approach to control non-linear systems that uses a family of controllers, each of which provides satisfactory control for a different operating point of the system. One or more observable variables, called the scheduling variables, are used to determine what operating region the system is currently in and to enable the appropriate linear controller. In an embodiment of the present disclosure, the gain-scheduling unit 50 is such as a microprocessor or a SoC (System on Chip), the scheduling variable is the detected temperature obtained by the temperature sensor 30. Specifically, the gain-scheduling unit 50 selects a schedule from a plurality of schedules according to the detected temperature and sends the selected schedule to the PID controller 70. In an embodiment, the gain-scheduling unit 50 sets a default value called “set-point” to the threshold temperature beforehand, and then takes the absolute value after subtracting said set-point from the value of the detected temperature. The gain-scheduling unit 50 uses this absolute value to determine which schedule should be selected from the plurality of schedules. As set forth above, the present disclosure does not limit the application form the scheduling parameter. However, practically, the matching condition of the selection from the plurality of schedules by the gain-scheduling unit 50 often adopts the detected temperature together with the set-point of the threshold temperature.

The plurality of schedules comprises an initial parameter set and at least one cooling parameter set. The cooling parameter set at least comprises a first parameter set and a second parameter set. Therefore, the gain-scheduling unit 50 has at least three parameter sets. The following table shows an example of three parameter sets.

| Set-Point | Detected Temperature | | | |
|---|---|---|---|---|
| 91° C. | PV(k) | K_{c} | Tᵢ | T_{d} |
| Second Parameter Set | PV(k) ≥ 89° C. | 3 | 14 | 0.5 |
| First Parameter Set | PV(k) ≥ 76° C. | 8 | 36 | 0.5 |
| Initial Parameter Set | PV(k) ≥− 109° C. | 0 | 0 | 0 |

Please refer to the above table. Every parameter set comprises three PID coefficients, K_{c}, Tᵢ, and T_{d}, all non-negative, denoting the coefficients for the proportional, integral and derivative terms respectively. It should be emphasized that values of initial parameters (i.e., three PID coefficients) in the initial parameter set are configured to zero. Additionally, the first parameter set and the second parameter set have a plurality of cooling parameters respectively, and each of the cooling parameters of the first parameter set is greater than each of the corresponding cooling parameters of the second parameter set. Since the cooling parameter sets comprise at least two parameter sets, assuming the above table needs to append to a third parameter set whose detected temperature is such as PV(k)≥90, each of the cooling parameters of the third parameter set should be configured smaller than each of the corresponding cooling parameters of the second parameter set. In other words, values of PID coefficients in the parameter set are set smaller when the detected temperature is closer to the set-point. Because the adjustment range decreases gradually, the temperature of the controlled area does not drop drastically for leading a waste of the additional electricity. Practically, about the settings of the specified value of PID coefficients, the server's administrator can directly configure the values or use a formula to calculate the values, and input these parameters into the gain-scheduling unit 50 before the server's dissipation system is activated.

Please refer to the numbers in the above table for the following illustration. The gain-scheduling unit 50 selects the initial parameter set to be input into the PID controller 70 when the detected temperature obtained by the temperature sensor 30 is greater than or equal to the initial temperature (such as −109 degrees Celsius) but is less than the first temperature (such as 76 degrees Celsius). The values of PID coefficients configured in the initial parameter set are all zero, “zero value setting” means the controlled area is in a transient state without the need of adjustment for the variation of temperature. In addition, since setting value of the initial temperature is far below from the threshold temperature, and it is impossible for the detected temperature of a running server to be lower than the configured initial temperature, so the situation that the detected temperature is smaller than the initial temperature is not under the consideration in this embodiment, and the corresponding PID coefficients can be viewed as zero. Please refer to the above table. The gain-scheduling unit 50 selects the first parameter set when the detected temperature is greater than or equal to the first temperature (such as 76 degrees Celsius) but less than the second temperature (such as 89 degrees Celsius). Specifically, when the temperature difference is smaller than 15 degrees, the gain-scheduling unit 50 outputs the PID coefficient (8, 36, 0.5) to the PID controller 70 to start the dissipation. It should be noticed that the gain-scheduling unit 50 directly configures the maximized PID coefficients after the detected temperature is greater than the first temperature. The gain-scheduling unit 50 then sends those PID coefficients to the PID controller 70 to enable the maximum speed of the fan 10 to prevent the server's heat from rapidly accumulating in a short time, leading the detected temperature to surpass the set-point. The gain-scheduling unit 50 selects the second parameter set when the detected temperature obtained by the temperature sensor 30 is greater than or equal to the second temperature (such as 89 degrees Celsius). This means that the temperature control is about to enter the steady state, so the fan 10 speed can be decreased to save the power consumption.

Practically, the PID controller 70 is such as an ARM (Advanced RISC Machine) chip. The PID controller 70 puts the parameters of the selected schedule into the PID algorithm's discrete formulae to calculate and control the rotation speed of the fan 10. The discrete formulae are listed below.

$$e ( k ) = r - PV ( k )$$

$${U}_{p} = {K}_{c} \times e ( k )$$

$${U}_{I} = \frac{{K}_{c}}{{T}_{i}} \sum \frac{e ( k ) + e ( k + 1 )}{2} Δ t$$

$${U}_{D} = \frac{- {K}_{c} {T}_{d} ( PV ( k ) - PV ( k - 1 ) )}{Δ t}$$

$${U}_{I} ( k ) = \{ \begin{matrix}{U}_{min} - {U}_{p} ( k ) , & if {U}_{p} ( k ) + {U}_{I} ( k ) < {U}_{min} \\ {U}_{max} - {U}_{p} ( k ) , & if {U}_{p} ( k ) + {U}_{I} ( k ) > {U}_{max}\end{matrix} \\ {U}_{total} = - ( {U}_{p} + {U}_{I} + {U}_{D} )$$

In the above formulas, r is the threshold temperature, PV(k) is the detected temperature, K_{c} is the coefficient of the proportional term, Tᵢ is the coefficient of integral term, T_{d} is the coefficient of the derivative term, U_{P} is the output of the fan speed of the proportional term, U₁ is the output of the fan speed of the integral term, U_{D} is the output of the fan speed of the derivative term, Uₘᵢₙ is the minimum output of the fan speed; Uₘₐₓ is the maximum output of the fan speed, Uₜₒₜₐₗ is the output of the total fan speed, and Δt is the system's sample time.

Please refer to FIG. 2, which is a flowchart of the temperature control method according to an embodiment of the present disclosure. The temperature sensor 30 gets the detected temperature of the controlled area, as shown in the step S1. The gain-scheduling unit 50 selects a schedule from a plurality of schedules according to the detected temperature, as shown in the step S3. The PID controller 70 computes the control signal of the fan speed according to the selected schedule and then outputs the control signal of the fan speed, as shown in the step S5. The fan 10 adjusts its rotation speed to control the temperature of the controlled area according to the control signal of the fan speed, as shown in the step S7. After the step S7, the method of the present disclosure moves back to the step S1 for continuously detecting the temperature of the controlled area and changing the schedule immediately according to the detected temperature. Therefore, the temperature of the controlled area can reach the interval of the steady state to achieve a balance point between the temperature control and the electricity consumption.

In sum, the present disclosure proposes a device and a method for controlling temperature, especially a device and a method for controlling the fan speed with schedules of PID coefficients. The present disclosure saves the time cost of adjustment of the PID coefficients and satisfies the performance's requirement of both the transient state and the steady state. The PID coefficients can be adjusted automatically when the server is operating. The present disclosure does not adjust the fan speed when the detected temperature does not reach the specified detected temperature so that saving the electricity cost of the fan.

What is claimed is:

1. A temperature control device adapted to a server, comprising:
a fan configured to drive airflows for controlling a temperature of a controlled area;
a temperature sensor disposed in the controlled area for getting a detected temperature of the controlled area;
a gain-scheduling unit electronically connected to the temperature sensor, wherein the gain-scheduling unit selects a schedule from a plurality of schedules according to the detected temperature, and the plurality of schedules comprises an initial parameter set and at least one cooling parameter set, said at least one cooling parameter set at least comprises a first parameter set and a second parameter set; the gain-scheduling unit selects the initial parameter set when the detected temperature is greater than or equal to an initial temperature and is less than a first temperature, the gain-scheduling unit selects the first parameter set when the detected temperature is greater than or equal to the first temperature and is less than a second temperature, the gain-scheduling unit selects the second parameter set when the detected temperature is greater than or equal to the second temperature; wherein the second temperature is greater than the first temperature and the first temperature is greater than the initial temperature; and
a PID controller electronically connected to the fan and the gain-scheduling unit for selectively controlling the fan according to the initial parameter set or said at least one cooling parameter set.

2. The temperature control device according to the claim 1, configured to control the detected temperature of the controlled area to be lower than a threshold temperature, wherein the temperature sensor gets the detected temperature according to an environmental temperature or a component temperature, and the threshold temperature is greater than or equal to the second temperature.

3. The temperature control device according to the claim 1, wherein the initial parameter set comprises a plurality of initial parameters, and values of the plurality of initial parameters are zero.

4. The temperature control device according to the claim 1, wherein the first parameter set and the second parameter set have a plurality of cooling parameters respectively, and each of the cooling parameters of the first parameter set is greater than each of the corresponding cooling parameters of the second parameter set.

5. A temperature control method adapted to a server, comprising:
getting a detected temperature of a controlled area of the server by a temperature sensor;
selecting a schedule from a plurality of schedules according to the detected temperature by a gain-scheduling unit, wherein the plurality of schedules comprises an initial parameter set and at least one cooling parameter set, said at least one cooling parameter set at least comprises a first parameter set and a second parameter set; the gain-scheduling unit selects the initial parameter set when the detected temperature is greater than or equal to an initial temperature and is less than a first temperature, the gain-scheduling unit selects the first parameter set when the detected temperature is greater than or equal to the first temperature and is less than a second temperature, the gain-scheduling unit selects the second parameter set when the detected temperature is greater than or equal to the second temperature; wherein the second temperature is greater than the first temperature and the first temperature is greater than the initial temperature;
calculating and outputting a control signal of fan speed according to the initial parameter set or said at least one cooling parameter set by a PID controller; and
adjusting a speed according to the control signal of fan speed by a fan.

6. The temperature control method according to claim 5, wherein the initial parameter set comprises a plurality of initial parameters, and values of the plurality of initial parameters are zero.

7. The temperature control method according to claim 5, wherein the first parameter set and the second parameter set have a plurality of cooling parameters respectively, and each of the cooling parameters of the first parameter set is greater than each of the corresponding cooling parameters of the second parameter set.
